(19) United States
(12) Patent Application Publication
(10) Pub. No.: US 2014/0269096 A1
(43) Pub. Date: Sep. 18, 2014

(54) NON-VOLATILE SEMICONDUCTOR MEMORY DEVICE AND METHOD OF PROGRAMMING THE SAME

(71) Applicant: KABUSHIKI KAISHA TOSHIBA, Minato-ku (JP)

(72) Inventors: Yoshihiko Kamata, Kanagawa-ken (JP); Koji Tabata, Kanagawa-ken (JP)

(73) Assignee: KABUSHIKI KAISHA TOSHIBA, Minato-ku (JP)

(21) Appl. No.: 14/020,174

(22) Filed: Sep. 6, 2013

(30) Foreign Application Priority Data
Mar. 18, 2013 (JP) 2013-055615

(51) Int. Cl. G11C 16/26; G11C 16/34

(52) U.S. Cl. CPC G11C 16/26; G11C 16/3459
USPC 365/185.21

(57) ABSTRACT

A first transistor can transfer a first voltage to a bit line. A latch circuit is electrically connected to a gate of the first transistor. A sensing portion is electrically connected to the bit line. A second transistor is connected to the sensing portion and the latch circuit. A third transistor is connected to the sensing portion and the bit line. A fourth transistor is connected to the second transistor and configured to transfer a first value corresponding to a voltage of the sensing node to the latch circuit. A first result is transferred as the first value to the latch circuit through the second and fourth transistor. The first result is obtained by turning on the third transistor for first and second periods. The first transistor transfers one of a ground potential and a second voltage to the bit line, as a voltage corresponding to the first result.

### CROSS-REFERENCE TO RELATED APPLICATION

This application is based upon and claims the benefit of priority from the prior Japanese Patent Application No. 2013-55615, filed on Mar. 18, 2013, the entire contents of which are incorporated herein by reference.

### FIELD

Embodiments described herein relate generally to a non-volatile semiconductor memory device and to a method of programming a non-volatile semiconductor memory device.

A NAND flash memory is provided with memory cells arranged in a matrix, sense amplifiers to store write data in the memory cells and so on.

Such a NAND flash memory needs to ensure reliability while reducing a circuit area of the memory.

### BRIEF DESCRIPTION OF THE DRAWINGS

FIG. 1 is a diagram showing a whole configuration of a non-volatile semiconductor memory device according to an embodiment;

FIG. 2 is a graph showing threshold distributions of memory cells provided in the non-volatile semiconductor memory device, and verify voltages for the memory cells;

FIG. 3 is a circuit diagram showing an example of a configuration of a sense amplifier provided in the non-volatile semiconductor memory device;

FIGS. 4A to 4E are flowcharts showing a writing operation of the non-volatile semiconductor memory device; and

FIGS. 5A to 15E are diagrams for explaining a specific example of the writing operation of the non-volatile semiconductor memory device, FIGS. 5A to 15A show an example circuit of the sense amplifier with signals, FIGS. 5B to 15B show timing charts of the signals, FIGS. 5C to 15C show data stored in a latch circuit of the example circuit, FIGS. 5D to 15D show data stored in a node of the example circuit, and FIGS. 5E to 15E are graphs showing the threshold distributions of the memory cells.

### DETAILED DESCRIPTION

A non-volatile semiconductor memory device of one embodiment includes a plurality of memory cells, a plurality of bit lines, a plurality of word lines, and a sense amplifier circuit including a plurality of sense amplifiers electrically connected to the bit lines. The bit lines are electrically connected to the memory cells. The word lines are electrically connected to gates of the memory cells.

Each of the sense amplifiers is provided with a first transistor, a latch circuit, a sensing portion, a second transistor, a third transistor and a fourth transistor. The first transistor is capable of transferring a first voltage to any one of the bit lines. The latch circuit is electrically connected to a gate of the first transistor. The sensing portion is electrically connected to the one of the bit lines. The second transistor is electrically connected to the sensing portion and the latch circuit. The third transistor is electrically connected to the sensing portion and the one of the bit lines. The fourth transistor is electrically connected to the second transistor and configured to transfer a first value corresponding to a voltage of the sensing node to the latch circuit.

In each of the sense amplifiers, a first result is transferred as the first value to the latch circuit through the second transistor and the fourth transistor after the first voltage is transferred to the one of the bit lines. The first result is obtained by turning on the third transistor for first and second periods which are different from each other. Further, the first transistor transfers one of a ground potential and a second voltage higher than the ground potential but lower than an internal voltage to the one of the bit lines, as a voltage corresponding to the first result.

Hereinafter, “transfer voltage (level) or potential” includes the meaning of “apply voltage (level) or potential”.

Hereinafter, a further embodiment will be described with reference to the drawings. In the drawings, the same reference numerals denote the same or similar portions respectively.

The following embodiment provides a non-volatile semiconductor memory device which is capable of controlling the threshold distributions of memory cells appropriately. Specifically, the embodiment can ensure reliability of data held in a memory cell while reducing a circuit area of a sense amplifier.

The embodiment shows an example of a non-volatile semiconductor memory device applied to a NAND flash memory. In the following description, “connect to an element” means “connect to an element via another element” as well as “connect to an element directly.”

### 1. Whole Configuration

The embodiment will be described with reference to FIG. 1. FIG. 1 is a block diagram showing a whole configuration of a non-volatile semiconductor memory device according to the embodiment.

A non-volatile semiconductor memory device 1 is provided with a memory cell array 2, a row decoder 3, a control unit 4, a voltage generation circuit 5, and a sense amplifier circuit 7.

### 1.1 Configuration of Memory Cell Array

The memory cell array 2 includes blocks BLK0 to BLKs. Each of the blocks BLK0 to BLKs has non-volatile memory cells MC. “s” is a natural number. Each of the blocks BLK0 to BLKs includes NAND strings 10. Each of the NAND strings 10 has a group of the non-volatile memory cells MC which are connected in series. Specifically, each NAND string 10 includes 64 pieces of the memory cells MC and select transistors ST1, ST2, for example.

Each memory cell MC is capable of holding data of two or more values, and has a floating gate (FG) structure including a floating gate i.e. a charge accumulation layer and a control gate. The floating gate is formed on a p-type semiconductor substrate via a gate insulating film. The control gate is formed on the floating gate via an inter-gate insulating film. The p-type semiconductor substrate has a source and a drain formed with a space arranged between the source and the drain. The structure of each memory cell MC may be a MONOS structure. A MONOS memory cell includes a charge accumulation layer, an insulating film (hereinafter, referred to as the block layer) and a control gate formed on the block layer.

The charge accumulation layer is, for example, an insulating film which is formed on a semiconductor substrate via a gate insulating film. The block layer is formed on the charge accumulation layer and having higher permittivity than the charge accumulation layer.

The control gates of the memory cells MC are electrically connected to word lines WL0 to WL63. The drains of the memory cells MC are electrically connected to bit lines BL0 to BLn. “n” is a natural number. The sources of the memory cells MC are electrically connected to source lines SL. Each memory cell MC is an n-channel MOS transistor. The number of memory cells MC is not limited to 64 but may be 128, 256, or 512, and the number is not limited.

Each memory cell MC shares a source and a drain with the adjacent memory cells MC. Current paths of the memory cells MC in each NAND string are arranged so as to be connected in series between the corresponding pair of select transistors ST1, ST2. The drain region of one of the series-connected memory cells MC which is arranged at one end in each NAND string is connected to the source region of the corresponding select transistor ST1. The source region of one of the series-connected memory cells MC which is arranged at the other end in each NAND string is connected to the drain region of the corresponding select transistor ST2.

The control gates of the memory cells MC arranged in the same row are connected in common to any one of the word lines WL0 to WL63. The gate electrodes of the select transistors ST1 arranged in the same row are connected in common to a select gate line SGD1. The gate electrodes of the select transistors ST2 arranged in the same row are connected in common to a select gate line SGS1. Hereinafter, the word lines WL0 to WL63 may be referred to as “word line(s) WL” simply when they do not need to be distinguished from one another. The drains of the select transistors ST1 arranged in the same column in the memory cell array 2 are connected in common to any one of the bit lines BL0 to BLn. Hereinafter, the bit lines BL0 to BLn may be referred to simply as “bit line(s) BL” when they do not need to be distinguished from one another. Each source of the select transistors ST2 is connected to each of the source lines SL.

Data writing is performed collectively for the memory cells MC connected to the same word line WL. Such a unit of write operation is called a page. Further, data erasing is performed collectively for the memory cells MC in the block BLK.

Such a configuration of the memory cell array 2 is mentioned, for example, in U.S. patent application Ser. No. 12/407,403 filed on Mar. 19, 2009 and entitled “THREE DIMENSIONAL STACKED NONVOLATILE SEMICONDUCTOR MEMORY.” Further, such a configuration is mentioned in U.S. patent application Ser. No. 12/406,524 filed on Mar. 18, 2009 and entitled “THREE DIMENSIONAL STACKED NONVOLATILE SEMICONDUCTOR MEMORY,” U.S. patent application Ser. No. 12/679,991 filed on Mar. 25, 2010 and entitled “NON-VOLATILE SEMICONDUCTOR MEMORY DEVICE AND METHOD OF MANUFACTURING THE SAME,” and U.S. patent application Ser. No. 12/532,030 filed on Mar. 23, 2009 and entitled “SEMICONDUCTOR MEMORY AND METHOD FOR MANUFACTURING SAME.” The entire contents of these patent applications are incorporated herein by reference.

### 1.2 Configuration of Peripheral Circuit

In FIG. 1, the row decoder 3 is connected to the word lines WL and selects and drives the word lines WL during data reading, writing, and erasing.

The control unit 4 generates a control signal which controls the sequence of data writing and erasing, and another control signal which controls data reading, by a command signal input through a controller 11 on the basis of an external control signal and a command signal (CMD) which are provided from a host 10 in accordance with operating modes. The control signals are sent to the row decoder 3, the voltage generation circuit 5, and the sense amplifier circuit 7. When specific commands are provided to the controller 11 from the host 10 or from the controller 11, various sequences of data reading and data writing described below can be performed in the non-volatile semiconductor memory device 1.

The control unit 4 may be arranged outside of the non-volatile semiconductor memory device 1. For example, the control unit 4 may be arranged in a semiconductor device other than the non-volatile semiconductor memory device 1, or may be arranged in the host.

In accordance with the control signals sent from the control unit 4, the voltage generation circuit 5 generates read voltages VREAD, VCGR, a write voltage VPGM, verify voltages VL, VH, and an erase voltage VERA. Further, the voltage generation circuit 5 generates voltages such as internal voltages VDD, VHSA which are necessary for various operations of the memory cell array 2, the row decoder 3 and the sense amplifier circuit 7.

The sense amplifier circuit 7 is connected to each of the bit lines BL and is provided with sense amplifiers 6 which will be described with reference to FIG. 3. The sense amplifier circuit 7 controls bit line voltages during data reading, data writing, and data erasing. During data reading, the sense amplifier circuit 7 detects data of the bit lines BL. Further, during data writing, the sense amplifier circuit 7 applies voltages corresponding to write data to the bit lines BL.

### 1.3 Threshold Distribution and Verify Voltages

The threshold distribution of the memory cells MC, and the verify voltages VL, VH will be described with reference to FIG. 2. In FIG. 2, the horizontal axis shows a threshold voltage or a verify voltage, and the vertical axis shows numbers of memory cells. The verify voltages are voltages for checking conduction and non-conduction of each NAND string 10 to determine whether desired data is written or not.

Each memory cell MC is capable of storing one of two values of data “0” and “1,” for example. As shown in FIG. 2, these two values are a level “E” and a level “A,” which are lower in voltage in this order. The level “E” is referred to as an erased state, and indicates a state where charges are not accumulated in the charge accumulation layer, for example. The value of each memory cell MC voltage rises from the level “E” to the level “A,” as the number of charges accumulated in the charge accumulation layer increases,

As shown in FIG. 2, the verify voltage VL is a voltage between a voltage V01 and the voltage VH, which satisfies a relation of V01<voltage VL<VH.

The verify voltage VH is a voltage between the voltages VL, Vth0 and satisfies a relation of voltage VL<voltage VH<Vth0.

As for the threshold distribution at the level A, the thresholds below the voltage VL belong to a region LF, and the memory cells MC within this range will be referred to as a first group. The thresholds which are equal to or larger than the voltage VL and which are equal to or smaller than the voltage VH belong to a region LP. The memory cells MC within this range will be referred to as a second group.

In this embodiment, in writing to a memory cell MC belonging to the second group, data writing is performed with the voltage of the bit line BL set larger than 0 V but smaller than the voltage VDD which is supplied to non-write bit lines BL. By performing the above writing, the thresholds of the memory cells in the second group can be shifted to the right side of the voltage VH and the threshold distribution can be narrowed. As a result, the gap between the threshold distributions of the levels A, E shown in FIG. 2 is broadened so that the read margin is increased. Accordingly, reliability of data stored in the memory cells MC can be enhanced.

In other words, data writing can be performed on memory cells MC which belong to the second group, under a condition where the potential difference between the gate and the channel is smaller than that of a normal writing or that of each memory cells MC belonging to the first group. By performing the above writing, the threshold of each memory cell MC belonging to the second group is raised gradually such that the threshold distribution narrows. Such a writing method is called a Quick Pass Write method (hereinafter, referred to as “QPW method”). The QPW method is described in U.S. patent application Ser. No. 10/051,372 filed on Jan. 22, 2002 and entitled “NONVOLATILE SEMICONDUCTOR MEMORY DEVICE,” for example. The entire content of this patent application is incorporated herein by reference.

### 1.4 Configuration of Sense Amplifier

The configuration of each sense amplifier 6 which forms the sense amplifier circuit 7 will be described with reference to FIG. 3. Each sense amplifier 6 includes n-channel MOS transistors 20 to 23, 25, 28 to 37, 39 to 41, p-channel MOS transistors 38, 42 to 45, and a capacitor element 27.

The control unit 4 shown in FIG. 1 controls the voltage levels of signals to be provided to the gates of the MOS transistors, the timings for providing the signals, and so on. The voltage generation circuit 5 generates the voltage levels of the signals.

Hereinafter, the threshold potential of each MOS transistor will be expressed using a reference numeral “Vth” to which the reference numeral of each MOS transistor is added. The reference numeral “Vth” indicates the threshold potential of a MOS transistor generally. For example, the threshold potential of the MOS transistor 22 will be expressed as “Vth22”.

One end of the current path of the MOS transistor 20 is connected to the corresponding bit line BL while the other end of the current path of the MOS transistor 20 is connected to a node N1, and a signal BLS is provided to the gate of the MOS transistor 20. The signal BLS is a signal which is set to a level “H (High)” during a read operation and a write operation. The signal BLS enables connection between the bit line BL and the sense amplifier 6.

One end of the current path of the MOS transistor 21 is connected to the node N1 while the other end of the current path of the MOS transistor 21 is grounded i.e. is held at a voltage VLSA, and a signal BLV is provided to the gate of the MOS transistor 21.

One end of the current path of the MOS transistor 22 is connected to the node N1 while the other end of the current path of the MOS transistor 22 is connected to a node SCOM, and a signal BLC is provided to the gate of the MOS transistor 22. The signal BLC is a signal for clamping the bit line BL at a predetermined potential. For example, when the signal BLC=(VQPW+Vth22) is given to the MOS transistor 22, the potential of the bit line BL becomes a voltage VQPW. For example, when the signal BLC=(Vblc+Vth22) is given during a read operation or a verify operation, the potential of the bit line BL becomes a voltage Vblc. The MOS transistor 22 forms a fifth transistor.

In writing in this embodiment, the threshold of each memory cell MC belonging to the second group is raised to shift the threshold distribution to or above the voltage VH. In this process, the signal BLC is equal to (VQPW+Vth22).

One end of the current path of the MOS transistor 23 is connected to the node SCOM, a voltage VHSA (=internal voltage) is supplied to the other end of the current path of the MOS transistor 23, and a signal BLX is provided to the gate of the MOS transistor 23. A voltage (Vblc+Vth23+BLC2BLX) is provided as the signal BLX during a read operation or a verify operation, for example.

Accordingly, the potential of the node SCOM during precharging is a voltage (Vblc+BLC2BLX).

The voltage BLC2BLX is a guard band voltage for transferring the voltage VHSA to the node SCOM securely. The voltage BLC2BLX is a voltage for raising the current driving force of the MOS transistor 23 so as to set the current driving force of the MOS transistor 23 larger than that of the MOS transistor 22. For example, in a case where signal BLX<signal BLC, the voltage to be supplied to the bit line BL is lowered to the signal BLX. In order to prevent such a situation, the voltage of the single BLX is set to a voltage higher than the voltage BLC.

One end of the current path of the MOS transistor 25 is connected to the node SCOM while the other end of the current path of the MOS transistor 25 is connected to a node SEN i.e. a sensing portion or sense capacitor, and a signal XXL is provided to the gate of the MOS transistor 25.

Vblc+Vth25+BLC2BLX+BLX2XXL is provided as the signal XXL during a read operation or a verify operation, for example. A voltage higher than that of the MOS transistor 23 by the voltage BLX2XXL is provided to the gate of the MOS transistor 25. The voltage BLX2XXL is a guard band voltage for transferring charges accumulated in the node SEN to the node SCOM. The MOS transistor 25 forms a third transistor.

The signals BLC, BLX, XXL satisfy a relation of signal BLC<signal BLX<signal XXL in terms of voltage. The current driving force of the MOS transistor 25 is higher than that of the MOS transistor 23 because when data “1” is to be sensed, the current which the MOS transistor 25 flows is set higher than the current which the MOS transistor 23 flows, so as to apply the potential of the node SEN to the bit line BL in priority.

In FIG. 3, a clock signal CLK is provided to one electrode of the capacitor element 27 through a node N2, and the other electrode of the capacitor element 27 is connected to the node SEN. The clock signal CLK has a function for boosting the potential of the node SEN. The voltage of the clock CLK is Vblc+BLC2BLX.

One end of the current path of the MOS transistor 28 is connected to the node N2, and a signal SEN is provided to the gate of the MOS transistor 28. The MOS transistor 28 is turned on or off according to the potential of the node SEN. Accordingly, the combination of the MOS transistor 28 and the node SEN can be called a sensing portion.

One end of the current path of the MOS transistor 29 is connected to the other end of the MOS transistor 28 while the other end of the current path of the MOS transistor 29 is connected to a node N3, and a signal STB is provided to the gate of the MOS transistor 29. The MOS transistor 29 forms a fourth transistor.

One end of the current path of the MOS transistor 30 is connected to the node SEN while the other end of the current path of the MOS transistor 30 is connected to the node N3, and a signal BLQ is provided to the gate of the MOS transistor 30. The signal BLQ can be a voltage VDD+Vth30+Vα. The voltage Vα is a guard band voltage added so as to transfer the voltage VDD which is transferred from the MOS transistor 34 described below to the node SEN securely.

One end of the current path of the MOS transistor 31 is connected to the node SEN, and a signal LSL is provided to the gate of the MOS transistor 31. One end of the current path of the MOS transistor 32 is connected to the other end of the current path of the MOS transistor 31 while the other end of the current path of the MOS transistor 32 is grounded i.e. is held at the voltage VLSA, and the gate of the MOS transistor 32 is connected to the node N3. The MOS transistors 31, 32 are transistors for calculating data.

One end of the current path of the MOS transistor 33 is connected to the node N3 while the other end of the current path of the MOS transistor 33 is connected to a node LAT_S. A signal STL is provided to the gate of the MOS transistor 33.

One end of the current path of the MOS transistor 35 is connected to the node N3 while the other end of the current path of the MOS transistor 35 is connected to a node DBUS. A signal DSW is provided to the gate of the MOS transistor 35. The other end of the current path of the MOS transistor 35 may be held at the ground potential when necessary. The MOS transistor 35 forms a sixth transistor.

The voltage VDD is supplied to one end of the current path of the MOS transistor 34, the other end of the current path of the MOS transistor 34 is connected to the node N3, and a signal LPC is provided to the gate of the MOS transistor 34. The node N3 and the one end of the current path of the MOS transistor 35 are connected by a wiring LBUS. The MOS transistor 34 charges the node SEN through the wiring LBUS.

A voltage VPRE VDD) is supplied to one end of the current path of the MOS transistor 38, the other end of the current path of the MOS transistor 38 is connected to a node N4, and a signal is provided from a node INV_S to the gate of the MOS transistor 38. One end of the current path of the MOS transistor 37 is connected to the node N4 while the other end of the current path of the MOS transistor 37 is grounded, and a signal is provided from the node INV_S to the gate of the MOS transistor 37. One end of the current path of the MOS transistor 36 is connected to the node N4 while the other end of the current path of the MOS transistor 36 is connected to the node SCOM, and a signal BLP is provided to the gate of the MOS transistor 36. The MOS transistor 37 or the MOS transistor 38 forms a first transistor.

The MOS transistors 36 to 38 are a group of transistors for transferring a predetermined voltage to the bit line BL. The MOS transistors 36 to 38 have a function of transferring 0 V or the voltage VPRE to the node SCOM, for example, in accordance with write data stored in a latch circuit SDL described below.

One end of the current path of the MOS transistor 39 is connected to the node LAT_S while the other end of the current path of the MOS transistor 39 is grounded, and the gate of the MOS transistor 39 is connected to the node INV_S.

One end of the current path of the MOS transistor 40 is connected to the node INV_S while the other end of the current path of the MOS transistor 40 is grounded, and the gate of the MOS transistor 40 is connected to the node LAT_S.

One end of the current path of the MOS transistor 41 is connected to the node INV_S while the other end of the current path of the MOS transistor 41 is connected to the node N3, and a signal STI is provided to the gate of the MOS transistor 41. Data of the node SEN is stored in the latch circuit SDL through the MOS transistor 41 or the MOS transistor 33. The MOS transistor 41 forms a second transistor.

The voltage VDD is supplied to one end of the current path of the MOS transistor 42, and a signal SLL is provided to the gate of the MOS transistor 42.

One end of the current path of the MOS transistor 43 is connected to the other end of the current path of the MOS transistor 42 while the other end of the current path of the MOS transistor 43 is connected to the node LAT_S. The gate of the MOS transistor 43 is connected to the node INV_S.

The voltage VDD is supplied to one end of the current path of the MOS transistor 44, and a signal SLI is provided to the gate of the MOS transistor 44.

One end of the current path of the MOS transistor 45 is connected to the other end of the current path of the MOS transistor 44 while the other end of the current path of the MOS transistor 45 is connected to the node INV_S. The gate of the MOS transistor 45 is connected to the node LAT_S.

The MOS transistors 39, 40, 43, 45 form the latch circuit SDL, and the latch circuit SDL holds data in the node LAT_S. For example, in a case of writing “1,” the latch circuit SDL holds a level “H” (=data “1”).

On the other hand, in the case of writing “0,” the latch circuit SDL holds a level “L (Low)” (=data “0”).

### 2. Write Operation

A write operation of each sense amplifier 6 of the non-volatile semiconductor memory device 1 will be described with reference to FIGS. 4A to 4E. Each of FIGS. 4A to 4E is a flowchart showing operations of the sense amplifier 6.

### 2.1 Overview of Write Operation

As shown in FIG. 4A, a first write operation is performed (step S1). Specifically, a write voltage (0 V) or a non-write voltage VDD is transferred to a bit line BL, and a voltage VPASS is transferred to each non-selected word line WL while the voltage VPGM is transferred to each selected word line WL. By these transfers, data writing is performed to memory cells MC.

Then, a verify operation is performed (step S2). The verify operation will be described in detail with reference to FIG. 4C below. In the verify operation, the bit line BL is clamped at the voltage Vblc, and the voltage VCGR is transferred to each selected word line WL while the voltage VREAD is transferred to each non-selected word line WL. Through the verify operation, writing situation can be detected as follows. It is determined that writing is not yet completed in any one of the NAND strings 10 shown in FIG. 1 when it is conductive. Further, it is determined that writing is completed in any one of the NAND strings 10 when it is not conductive.

A second write operation is performed. Specifically, the write voltage (0 V) is transferred through the corresponding bit line BL to the memory cells MC included in any one of the NAND strings 10 which is conductive in step S2. The non-write voltage (VDD) is transferred through the corresponding bit line BL to the memory cells MC included in any one of the NAND strings 10 which is not conductive in step S2 due to completion of writing. Further, the non-write voltage (VDD) is transferred through the corresponding bit line BL to the memory cells MC which are set to non-write from the start (step S3).

Then, for the memory cells of the second group belonging to region LP, the voltage VQPW which is higher than 0 V but lower than the voltage VDD is transferred to the bit line BL. A write operation for the memory cells is performed at the same time when a write operation is performed for the memory cells MC connected to the bit line BL to which the write voltage is previously transferred in step S3 (step 4).

### 2.2 Details of Write Operation

The operation of step S1 will be described in detail with reference to FIG. 4B. In a case of performing a write operation, the control unit 4 transfers write data “1” or “0” from a data latch circuit XDL for caching (not shown) to the latch circuit SDL (step S10). Then, the control unit 4 transfers the voltage VPRE (voltage VDD) or the ground potential to a bit line BL in accordance with write data stored in the latch circuit SDL, and a first write operation is performed (step S11). The data latch circuit XDL is a latch circuit which holds data when data transfer such as data-in or data-out is performed with outside of a chip via a chip interface.

Details of the operation of step S2 will be described with reference to FIG. 4C. The verify voltage VH is transferred to each of the word lines WL connected to the memory cells MC on which writing is performed in step S1, and a first verify operation is performed (step S20).

Then, the verify result stored in the node SEN as a result of the verify operation is transferred to the latch circuit SDL (step S21). At this time point, it is possible to detect whether or not the memory cells MC on which the data writing has been performed pass the verification i.e. whether or not the writing is performed to attain a predetermined threshold value.

Further, the verify result stored in the latch circuit SDL is inverted and transferred to the node SEN (step S22). This transfer specifies the memory cells MC failing to pass the verification, i.e. the memory cells MC to be subjected to a further writing.

Then, the word lines WL connected to the memory cells MC on which writing has been performed are maintained at the voltage VH, and a second verify operation is performed (step S23). At this time, the sensing time of the sense amplifier 6 is set shorter than that in step S20 to perform the verify operation using the verify voltage VL.

Then, the result of the verification using the verify voltage VL is stored in the node SEN (step S24). The second verify operation specifies the memory cells MC (the voltage of the bit lines BL connected to the memory cells=VQPW) belonging to the second group which have a narrower threshold distribution than the memory cells MC belonging to the first group described with reference to FIG. 2. The second verify operation specifies the memory cells MC which need weak writing for raising threshold.

Although the levels of the word lines WL are switched between the voltages VL, VH so as to perform the verify operation using the verify voltage VH, VL, but not limited to such a method.

The operation of step S3 will be described in detail with reference to FIG. 4D. Preparation for another write operation (a second write operation) is performed using the data stored in the latch circuit SDL in step S21. In the preparation, a write permitting voltage (0 V) is transferred to the bit line BL in a case where the data held in the latch circuit SDL is “0” in step S21. On the other hand, a write forbidding voltage (voltage VDD) is transferred to the bit line BL in a case of the data held in the latch circuit SDL is “1” (step S30).

The operation of step S4 will be described in detail with reference to FIG. 4E. The verify result obtained in step S24 is transferred to the latch circuit SDL (step S40). The transfer leads to execution of operations including a second writing in step S41 or step S44 which will be described below. A write operation in a flow from step S40 to step S43 through steps S41, S42 is performed a plurality of times. In other words, a write operation which involves applying the voltage VQPW to the bit line BL is performed a plurality of times. A write operation in a flow from step S40 to step S45 through step S44 is performed only once, for example. Specifically, a write operation which involves applying the voltage VQPW to the bit line BL is performed once.

The former write operation to be performed a plurality of times will be described. After step S40, a refresh operation is performed. The potential of the bit line BL charged in step S30 is transferred to the node SEN. For example, based on the data stored in the latch circuit SDL in step S21, the node SEN is set to a level “L” in a case where the bit line BL is at 0 V. The node SEN is set to a level “H” in a case where the bit line BL is at the voltage VDD. The refresh operation is performed to prevent erasure of the charges accumulated in the node SEN at the timing of step S22.

Then, a voltage based on the data stored in the latch circuit SDL in step S40 is transferred to the bit line BL (step S42). In this step, a signal BLC provided to the gate of the MOS transistor 22 in FIG. 3 is set to the voltage (VQPW+Vth22).

Thus, the voltage of the bit line BL corresponding to the memory cells MC belonging to the second group is set to VQPW (<voltage VDD). Consequently, the threshold distribution of the memory cells MC in the second group is raised to desired values. The write operation ends once the threshold distribution of the memory cells MC in the second group is raised to the desired values as described above (step S43).

The latter write operation which is performed only once will be described. The operation involves no refresh operation. The voltage corresponding to the write data stored in the latch circuit SDL in step S40 is transferred to the bit line BL, and data writing is performed (step S44). Specifically, in step S44, writing similar to that in step S42 is performed.

An operation of writing data “0” is performed on the memory cells MC having a threshold distribution not above the verify voltage VH in step S20 so that the threshold distribution can shift beyond the verify voltage VH.

As described above, through the operations from step S40 to step S45 via step S44, the memory cells MC located in the threshold distribution from the voltage VL to the voltage VH, i.e. the memory cells MC belonging to the second group is regarded as “PASS” i.e. exceeding the verify voltage VH by the second write operation. Thus, the write operation for the memory cells MC located in this threshold distribution is terminated (step S45).

### 3. Example of Write Operation

The specific operations from step S10 to S45 will be described by dealing with a sense amplifier 6 with reference to FIGS. 5A to 15E.

3.1 Data Transfer from Data Latch Circuit XDL to Latch Circuit SDL (Corresponding to Step S10)

As shown in FIG. 5A, write data is transferred from the data latch circuit XDL (not shown) to the latch circuit SDL. In this step, as shown in FIG. 5B, the signals LPC, DSW, and STI are respectively set to a level “H” at time t0 to transfer the write data from the data latch circuit XDL to the latch circuit SDL.

As shown in FIG. 5A, the latch circuit SDL holds data “1” and the node LAT_S is set to a level “H”, in a case where the write data is “1” and the threshold distribution of the memory cells MC which are writing targets is aimed to be set to an erasure level.

On the other hand, the latch circuit SDL holds data “0” and the node LAT_S is set to a level “L”, in a case where the write data is “0.”

At this time point, as shown in FIGS. 5D and 5E, the potential of the node SEN is at a level “L,” and the threshold distribution of the memory cells which are writing targets MC is also the level “E” i.e. an erased state.

### 3.2 Programming (Corresponding to Step S11)

Then, as shown in FIG. 6A, a voltage corresponding to the write data stored in the latch circuit SDL is transferred to the bit line BL. In this step, as shown in FIG. 6B, the signals BLP, BLC, BLS are set to a level “H” at time t0.

For example, the bit line BL is set to the voltage VDD in a case where the latch circuit SDL holds data “1”. The bit line BL is set to 0 V in a case where the latch circuit SDL holds data “0.”

Then, the voltage VPGM is supplied to each selected word line WL while the voltage VPASS is supplied to each non-selected word line WL to perform data writing. As a result, as shown in FIG. 6E, the memory cells MC hold a threshold distribution corresponding to the write data “1” or “0.”

The states of FIGS. 6C and 6D remain unchanged compared with those of FIGS. 5C and 5D.

### 3.3 Precharge, Discharge, Charge Share, Verify, and Transfer to Latch Circuit SDL (Corresponding to Steps S20, S21)

Verification of the written data is performed, and the verify result is transferred to the latch circuit SDL. Specifically, as shown in FIG. 7A, the bit line BL is precharged, and, after the precharge, discharging and further sensing of the bit line BL is performed. Subsequently, the value of the node SEN which is the sense result is transferred to the latch circuit SDL.

As shown in FIG. 7B, in the precharge, the signals BLX, BLC and BLS are set to a level “H” at time t0 to transfer the voltage Vblc to the bit line BL. The node SEN is charged at the same time with the precharge.

After starting discharge of the bit line BL, the signals XXL, BLC and BLS are set to a level “H” to perform charge share between the bit line BL and the node SEN. Subsequently, the signal XXL is set back to a level “L” at time t3. By setting the signal XXL back to the level “L” at the time t3 as described above, the verify level can be at the voltage VH as shown in FIG. 7E. By the operations up to this time point, a verify result is stored in the node SEN.

The value of the node SEN changes as a result of the verify operation using the verify voltage VH. Specifically, as shown in FIG. 7D, the voltage of the node SEN is set to the level “L” in a case where the verify targets are memory cells MC having threshold voltages below the verify voltage VH in the threshold distribution. The voltage of the node SEN is set to the level “H” in a case where the verify targets are memory cells MC having threshold voltages equal to or above the verify voltage VH in the threshold distribution.

Subsequently, as shown in FIG. 7B, the signals STB, STI are set to a level “H” at time t4 to transfer the voltage level of the node SEN to the latch circuit SDL.

As shown in FIG. 7C, memory cells MC which cause the node LAT_S to shift from the level “L” to the level “H” are those which have write data “1” or which exceed the verify voltage VH and can pass the verification.

### 3.4 Charge of Node SEN and Transfer of Inverted Data of Latch Circuit SDL to Node SEN

As shown in FIG. 8A, the node SEN is charged through the MOS transistors 34, 30, and inverted data stored in the latch circuit SDL is transferred to the node SEN through the MOS transistors 33, 32. By the transfer, the node SEN shifts to the level “L” in the case of memory cells MC to which data “1” is written or which exceed the verify voltage VH, as shown in FIG. 8D.

In this step, as shown in FIG. 8B, the signals LPC, BLQ are set to a level “H” at time t0, and then the signals STL, LSL are set to a level “H” at time t2.

### 3.5 Precharge, Discharge, Charge Share, and Verify

As shown in FIG. 9A, a verify operation is performed again. Specifically, a verify operation is performed using the verify voltage VL which is lower than the verify voltage VH. The verify operation is performed for the purpose of specifying the memory cells MC in the second group.

The verify operation will be described in detail. The signals BLX, BLC and BLS are set to the level “H” at time t0 to transfer the voltage Vblc to the bit line BL and to precharge the bit line BL. Further, discharge of the bit line BL is performed. Then, as shown in FIG. 9B, the signals BLS, BLC and XXL are set to the level “H” at time t2 to perform charge share.

The period for which the signal XXL is at the level “H” is from t2 to t2′. This is a period shorter than the period from t2 to t3 for which the signals BLS, BLC are at the level “H”. This operation allows execution of a verify operation using the verify voltage VL as shown in FIG. 9E.

As shown in FIG. 9D, the node SEN is shifted from the level “H” to the level “L” in the case of memory cells MC belonging to the first group. However, the node SEN is maintained at the level “H” in the case of memory cells MC not in the first group but in a threshold distribution above the verify voltage VL.

### 3.6 Write Operation

As shown in FIG. 10A, preparation for a write (programming) operation is performed based on the stored data in the latch circuit SDL shown in FIG. 7C. Specifically, as shown in FIG. 10B, the signals BLP, BLC and BLS are set to the level “H” at time t0. The voltage VPRE (=voltage VDD) is transferred to the bit lines BL connected to the memory cells MC which pass the verification using the verify voltage VH and to the memory cells MC which are non-write targets from the start. 0 V is transferred to the other bit lines BL. The stored data in the node LAT_S and the node SEN and the threshold distribution remain unchanged.

3.7 Transfer of Data from Node SEN to Latch Circuit SDL

As shown in FIG. 11A, the value of the node SEN is transferred to the latch circuit SDL. As shown in FIG. 11D, in the case of memory cells MC belonging to the second group, the node SEN is at the level “H.” Thus, when the value of the node SEN (level “H”) is transferred to the latch circuit SDL, the latch circuit SDL shifts from the level “L” to the level “H” as shown in FIG. 11C.

The signals STB, STI are set to the level “H” at time t0 to transfer the value of the node SEN to the node INV_S. For example, when the node SEN is at the level “H,” the node INV_S is at the ground potential, and the node LAT_S holds the level “H.”

The clock CLK is at the ground potential at the timing when the signals STB, STI are set to the level “H” as shown in FIG. 11B. Thus, when the node SEN is at the level “H,” the node INV_S is at the ground potential. The operations of step S41 to S43 will be described below.

### 3.8 Charge of Node SEN and Transfer of Voltage of Bit Line to Node SEN

As shown in FIG. 12A, the node SEN is charged to the level “H” through the MOS transistors 34, 30. Then, the potential transferred to the bit line BL in FIG. 10A is transferred to the node SEN.

Specifically, as shown in FIG. 10C, the bit lines BL connected to the memory cells MC belonging to the first group and located in the region LF in the threshold distribution and to the memory cells MC belonging to the second group are at 0 V (=level “L”). The bit lines BL connected to the other memory cells MC are at the voltage VDD (=level “H”). Either of these voltages is transferred to the node SEN. As a result, the node SEN shifts from the level “H” to the level “L” in the case of memory cells MC belonging to the first group or the second group as shown in FIG. 12D.

The signals LPC, BLQ are set to the level “H” at time to. Then, the signals BLS, BLC and XXL are each set to the level “H” at time t=2 so that the voltage from the bit line BL can be transferred to the node SEN.

The voltages in FIGS. 12C and 12E remain unchanged.

### 3.9 Write Operation Using Signal BLC=(VQPW+Vth22)

The write operation will be described with reference to FIG. 13A. As described with reference to FIG. 11C, the data stored in the latch circuit SDL is the level “L” in the case of memory cells MC belonging to the first group, and the data stored in the latch circuit SDL is the level “H” in the case of the other memory cells MC.

In the case of memory cells MC belonging to the first group, a normal writing is performed because the voltage transferred to the bit line BL is 0 V. However, in the case of memory cells MC belonging to the second group, the voltage VQPW is transferred to the bit line BL. Thus, a writing in which the potential difference between the word line WL and the channel is small is performed on the memory cells MC in the threshold distribution belonging to the second group.

By the execution of the above writing, a data writing is performed on the memory cells MC belonging to the second group such that the memory cells MC belonging to the second group exceed the voltage VH.

Even when the voltage VDD is transferred to the node SCOM through the MOS transistor 37, the voltage VDD is lowered by the MOS transistor 22 to the voltage VQPW because the signal BLC is the voltage (VQPW+Vth22).

In the case of the memory cells MC in the erasure state or the memory cells MC having threshold voltages equal to or higher than VH, the voltage VDD is already transferred to the bit line BL as described with reference to FIG. 10A. Thus, the bit line BL is cut off when the signal BLC i.e. the voltage (VQPW+Vth22) is applied.

Further, as a verify preparation operation, calculation for a verify operation is performed. As shown in FIG. 14A, the latch circuit SDL is reset once, and the data in the node SEN is transferred to the latch circuit SDL. The data in the node SEN is as shown in FIG. 12D and is the level “L” in the case of memory cells MC belonging to the first and second groups.

The signals STI, STB shift in the same way as FIG. 11B.

As a result, the stored data in the latch circuit SDL remains at the level “L” in the case of memory cells MC belonging to the first and second groups. The stored data in the latch circuit SDL shifts from the level “L” to the level “H” in the case of the other memory cells MC such as those in the erasure state and those at or above the voltage VH.

In the case of the memory cells MC belonging to the first and second groups, the memory cells MC will be subjected to verification in the subsequent verify operation as well.

Hereinafter, the operations of steps S44 and S45 will be described.

### 4.0 Write Operation

As shown in FIG. 15A, a voltage corresponding to the write data in the latch circuit SDL is transferred to the bit line BL, and a write operation is performed. The write operation is similar to the write operation described with reference to FIG. 13A.

### 4.1 Termination of Write to Memory Cells Belonging to Second Group

As shown in FIG. 15C, the operations of steps S41 to S43 are not performed on the memory cells MC belonging to the second group. The memory cells MC belonging to the second group are deemed as passing the verification using verify voltage VH and are not subjected to the subsequent verification. Thus, no additional writing is performed on the memory cells MC belonging to the second group.

Accordingly, the writing of the memory cells MC belonging to the second group is terminated. However, additional writing is performed on the memory cells MC in the first group in a case where the threshold distribution of these memory cells are within the region LP between the voltages VL, VH shown in FIG. 15E, even after performing writing similar to that described with reference to FIG. 13A. Further, additional writing needs to be performed in a manner similar to that described with reference to FIG. 13A also in a case where the threshold distribution of the memory cells MC belonging to the first group shifts to the region LF at or below the voltage VL shown in FIG. 15E.

The non-volatile semiconductor memory device according to the embodiment can achieve both a reduced area and ensured reliability. Specifically, in the embodiment, the node SEN functions as a latch portion. Thus, the threshold distribution of memory cells can be narrowed without a latch circuit such as a UDL which stores information indicating whether or not a memory cell MC for carrying out a QPW method, for example.

The embodiment can reduce the circuit area of each sense amplifier 6 and ensure reliability at the same time, for example, compared to a non-volatile semiconductor memory device including a latch circuit such as a UDL. For instance, according to the embodiment, the threshold distribution of the memory cells MC are narrowed as described above so that the reading margin is enhanced. Accordingly, it is possible to reduce problems such as reading error in data reading.

When the wording “electrically connected” or “electrically linked” is used in the embodiment described above, it includes a meaning that one element is linked to another element through yet another element.

In the embodiment, the period of time (a sensing time) for which the signal XXL is turned on is changed in order to read the two verify voltages i.e. the voltages VL, VH as different voltages, but not limited to the case. Specifically, the voltage transferred to the word lines WL may be switched between the levels of the voltages VH, VL simply in order to read the two verify voltages as different voltages.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A non-volatile semiconductor memory device, comprising:
a plurality of memory cells;
a plurality of bit lines electrically connected to the memory cells electrically;
a plurality of word lines electrically connected to gates of the memory cells; and
a sense amplifier circuit including a plurality of sense amplifiers electrically connected to the bit lines,
each of the sense amplifiers including
a first transistor capable of transferring a first voltage to any one of the bit lines,
a latch circuit electrically connected to a gate of the first transistor,
a sensing portion electrically connected to the one of the bit lines,
a second transistor electrically connected to the sensing portion and the latch circuit,
a third transistor electrically connected to the sensing portion and the one of the bit lines, and
a fourth transistor electrically connected to the second transistor and configured to transfer a first value corresponding to a voltage of the sensing portion to the latch circuit, wherein
a first result is transferred as the first value to the latch circuit through the second transistor and the fourth transistor after the first voltage is transferred to the one of the bit lines, the first result being obtained by turning on the third transistor for first and second periods which are different from each other, and
further, the first transistor transfers one of a ground potential and a second voltage higher than the ground potential but lower than an internal voltage to the one of the bit lines, as a voltage corresponding to the first result.

2. The device according to claim 1, wherein a first signal is provided to the second transistor, a second signal different from the first signal is provided to the fourth transistor, and the first and second signals are activated after the first voltage is transferred to the one of the bit lines.

3. The device according to claim 2, further comprising a fifth transistor connected to the third transistor in series and configured to clamp the one of the bit lines at the first voltage, wherein a voltage to be provided to a gate of the fifth transistor is set to a voltage lower than the internal voltage for clamping, when the voltage corresponding to the first result is transferred to the one of the bit lines.

4. The device according to claim 3, wherein one ends of the fourth transistor and the second transistor are connected to a wiring, the wiring is electrically connectable to an outside through a sixth transistor, and the latch circuit is configured to exchange the data with the outside through the sixth transistor.

5. The device according to claim 4, wherein the third transistor is on for the first period, the third transistor is on for the second period, and the second period is shorter than the first period.

6. The device according to claim 4, further comprising a seventh transistor which is electrically connected to the wiring for providing the internal voltage, wherein the second, the sixth and the seventh transistors are turned on.

7. The device according to claim 6, further comprising an eighth transistor which is electrically connected between the fifth transistor and the bit line, wherein the first, the fifth and the eighth transistors are turned on so that the first voltage is transferred to the bit line.

8. The device according to claim 7, further comprising a ninth transistor which provides an internal voltage for precharging the bit line, wherein the first, the third, the fourth, the fifth, the eighth and the ninth transistors are controlled so that the bit line is precharged, then the bit line is discharged, further the bit line is sensed by the sensing portion, then the first value of the sensing portion is transferred to the latch circuit as a sensing result.

9. The device according to claim 8, further comprising a tenth transistor electrically connected between the latch circuit and the wiring, an eleventh transistor electrically connected between the sensing portion and the wiring, and a twelfth transistor electrically connected to the eleventh transistor, wherein the seventh, the tenth, the eleventh and the twelfth transistors are controlled so that an inverted date of data of the latch circuit is transferred to the sensing portion after the sensing portion is charged through the seventh and the eleventh transistors.

10. The device according to claim 9, wherein the third, the eighth and the ninth transistors are turned on so that the bit line is precharged, further the bit line is discharged, and, after the discharge, the third, the fifth and the eighth transistors are turned on.

11. The device according to claim 10, wherein the first, the fifth and the eighth transistors are turned on, after the third, the fifth and the eighth transistors are turned on.

12. The device according to claim 11, wherein the second and the fourth transistors are turned on, after the first, the fifth and the eighth transistors are turned on.

13. A method of programming the non-volatile semiconductor memory device according to claim 1, comprising:
performing a write operation to one of the memory cells;
performing a first verify operation in which a current flowing through the one of the bit lines is sensed for a first period, checking whether or not a threshold distribution is shifted to a first threshold level, and storing a checked result in the sensing portion and the latch circuit as a first result;
performing a second verify operation in which a current flowing through the one of the bit lines is sensed for a second period shorter than the first period, checking whether or not the threshold distribution is shifted to a second threshold level lower than the first threshold level, and storing a checked result in the sensing portion as a second result;
transferring a write voltage to the one of the bit lines in accordance with write data of the latch circuit;
transferring a third result to the latch circuit through the second transistor and the fourth transistor connected to the sensing portion, the third result being obtained from the first result and the second result and being stored in the sensing portion and; and
transferring one of the ground potential and the second voltage higher than the ground potential but lower than the internal voltage to the one of the bit lines in accordance with the third result.

14. The method according to claim 13, wherein
the transfer of the third result to the latch circuit is to activate first and second signals provided to the second transistor and the fourth transistor,
the third result indicates another write to the one of the memory cells in a case where the third result shows that the one of the memory cells belongs to a threshold distribution below the second threshold level, and
the third result indicates a weak write to the one of the memory cells in a case where the third result shows that the one of the memory cells belongs to a threshold distribution above the second threshold level but below the first threshold level.

15. A method according to claim 14, wherein the transfer of the first voltage is performed by switching on a fifth transistor which clamps the voltage of the one of the bit lines.
